(19) United States
(12) Patent Application Publication
(10) Pub. No.: US 2026/0058638 A1
(43) Pub. Date: Feb. 26, 2026

(54) MEMS OSCILLATING ELEMENT AND METHOD FOR OPERATING A MEMS OSCILLATING ELEMENT

(71) Applicant: Robert Bosch GmbH, Stuttgart (DE)

(72) Inventor: Johannes Classen, Reutlingen (DE)

(21) Appl. No.: 19/280,203

(22) Filed: Jul. 25, 2025

(30) Foreign Application Priority Data
Aug. 22, 2024 (DE) 10 2024 207 998.7

(51) Int. Cl. H03H 9/24; B81B 3/00

(52) U.S. Cl. CPC H03H 9/2447; B81B 3/0051

(57) ABSTRACT

A micro-electromechanical (MEMS) oscillating element. The MEMS oscillating element includes: a first component; a movable component mounted to be movable relative to the first component in a first direction, the movable component assumes a stop position relative to the first component upon a sufficiently large deflection, and contacts the first component in the stop position; at least one actuator component configured as a bending beam clamped on both sides with a beam longitudinal axis running perpendicular to the first direction. The actuator component is configured to selectively assume an undeformed configuration and a deformed configuration, in which the at least one actuator component is at least partially deflected perpendicular to its beam longitudinal axis. The at least one actuator component, in the deformed configuration, transmits a force between the first component and the movable component if the movable component is in the stop position.

### CROSS REFERENCE

The present application claims the benefit under 35 U.S. C. § 119 of Germany Patent Application No. DE 10 2024 207 998.7 filed on Aug. 22, 2024, which is expressly incorporated herein by reference in its entirety.

### FIELD

The present invention relates to a micromechanical (MEMS) oscillating element and a method for operating a MEMS oscillating element. In particular, the present invention relates to an inertial sensor and a method for operating an inertial sensor.

### BACKGROUND INFORMATION

Micromechanical (MEMS) oscillating elements are mass-produced for various applications in the automotive and consumer sectors, often as sensors for measuring acceleration, angular rate, or pressure changes. The sensor principle of such sensors is in many cases based on an oscillating system in which a spring-elastic movable electrode element and a fixed counter electrode form a capacitor. When the movable electrode element is deflected relative to the fixed counter electrode, the capacitance of the capacitor changes, which is measurable and serves as a starting point for determining the quantity to be determined.

A possible failure pattern in the case of frequently repeated shock loads on such sensors is sticking, in which the movable electrode element gets stuck on a mechanical fixed stop as soon as the adhesion forces in the stop are greater than the restoring forces of the spring-elastic bearing. To reduce the adhesion forces, a so-called anti-stiction coating (ASC) is often used, which is applied to the sensor surface after it has been exposed. However, if a sensor strikes a fixed stop very often, the ASC can be damaged, such that the sensor eventually shows an increased tendency to stick.

It is an object of the present invention to provide an alternative or improved MEMS oscillating element and a method for operating a MEMS oscillating element.

### SUMMARY

The object of the present invention may be achieved by means of a MEMS oscillating element, as well as by a method for operating a MEMS oscillating element. Advantageous further developments, additional features and/or advantages of the present invention emerge from the disclosure herein.

It should be noted that all features mentioned in connection with the disclosed method can also be designs of the disclosed system, and vice versa.

According to a first aspect, the present invention provides a micro-electromechanical (MEMS) oscillating element. According to an example embodiment of the present invention, the MEMS oscillating element includes the following:

a first component;

a movable component that is mounted so as to be movable relative to the first component at least in a first direction;

wherein the movable component assumes a stop position relative to the first component in the event of a sufficiently large deflection, wherein the movable component contacts the first component in the stop position at least at a first stop point;

at least one actuator component, which is designed as a bending beam clamped on both sides with a beam longitudinal axis running perpendicular to the first direction, wherein the at least one actuator component is designed, depending on an activation, to selectively assume an undeformed configuration and a deformed configuration, in which the at least one actuator component is at least partially deflected perpendicular to its beam longitudinal axis; wherein the at least one actuator component is designed, in the deformed configuration, to transmit a force between the first component and the movable component when the movable component is in the stop position.

According to an example embodiment of the present invention, the at least one actuator component can be designed to change from the undeformed configuration to the deformed configuration when subjected to a voltage, wherein in particular the at least one actuator component is heated from a first temperature to a buckling temperature and is transferred from the undeformed to the deformed configuration.

The at least one actuator component can be configured in such a way that when the buckling temperature is reached, it buckles abruptly from the undeformed configuration to the deformed configuration.

The at least one actuator component can be configured in such a way that, upon buckling into the deformed configuration, it exerts a mechanical impulse on the first component and/or the movable component when the movable component is in the stop position.

The at least one actuator component can be designed in such a way that the mechanical impulse releases a stiction state between the first component and the movable component.

The at least one actuator component can exhibit an initial deformation perpendicular to the beam longitudinal axis in the undeformed configuration, such that a position of the deformed configuration relative to the undeformed configuration is predetermined.

In the deformed configuration, the at least one actuator component can be arranged closer to the movable component and further spaced away from the first component than in the undeformed configuration.

According to an example embodiment of the present invention, the MEMS oscillating element can comprise a control device that is connected to a voltage supply device and is configured to detect a stiction state between the first component and the movable component and to apply a voltage to the at least one actuator component via the voltage supply device.

The control device can be configured to apply a voltage to the at least one actuator component in such a way that the at least one actuator component buckles from the undeformed configuration into the deformed configuration in a series of temporally spaced pulses.

The control device can be configured to increase the voltage applied to the at least one actuator component, while the at least one actuator component is in the deformed configuration.

The MEMS oscillating element can be designed as a sensor element and the movable component can comprise a seismic mass.

According to an example embodiment of the present invention, the MEMS oscillating element can comprise a substrate with a main extension plane and at least one at least partially self-supporting electrode, wherein:

the movable component is movably fastened to the substrate in a suspension region about a torsion axis parallel to the main extension plane;

the movable component exhibits an asymmetric mass distribution with respect to the torsion axis;

the at least one electrode is connected to the substrate in a connection region; and

the connection region is arranged perpendicular to the torsion axis and parallel to the main extension plane in the region of the suspension region and/or immediately adjacent to the suspension region.

The at least one electrode can be arranged in a direction perpendicular to the main extension plane between the movable component and the substrate or the movable component can be arranged in the direction perpendicular to the main extension plane between the at least one electrode and the substrate.

In a direction perpendicular to the main extension plane, in each case an electrode can be arranged both above and below the movable component.

The longitudinal axis of the beam of the at least one actuator component can be arranged parallel to the main extension plane of the substrate.

The at least one actuator component can be arranged above or below the movable component.

According to an example embodiment of the present invention, the MEMS oscillating element can comprise a first actuator component and a second actuator component, wherein the first actuator component and the second actuator component are arranged in a plane parallel to the main extension plane and on opposite sides of the torsion axis in relation to the torsion axis.

According to a further aspect, the present invention provides a method for operating a micro-electromechanical (MEMS) oscillating element, the MEMS oscillating element comprising a first component, a movable component that is mounted so as to be movable relative to the first component at least in a first direction and that contacts the first component in a stop position upon a sufficiently large deflection, and at least one actuator component that is designed as a bending beam clamped on both sides with a beam longitudinal axis running perpendicular to the first direction and that selectively assumes an undeformed configuration and a deformed configuration, in which it is deflected at least partially perpendicular to the beam longitudinal axis. According to an example embodiment of the present invention, the method comprises the following steps:
S1—Recognizing a stiction state in which the movable component is held to the first component by a force;
S2—Heating the at least one actuator component in such a way that the at least one actuator component buckles perpendicular to the longitudinal axis of the beam from the undeformed to the deformed configuration and releases the movable component from the first component by a mechanical impulse.

Step S2 can comprise applying a voltage to the at least one actuator component in order to heat the at least one actuator component by electrical resistance heating.

According to an example embodiment of the present invention, the method can comprise the following steps of:
S3—Recognizing that the stiction state no longer exists;
S4—Transferring the at least one actuator component from the deformed to the undeformed configuration.

Step S4 can comprise canceling a voltage across the at least one actuator component.

### BRIEF DESCRIPTION OF THE DRAWINGS

The present invention is explained in more detail below using exemplary embodiments with reference to the schematic and not-to-scale figures.

FIG. 1 shows schematically, an example embodiment of a MEMS oscillating element, according to the present invention.

FIG. 2 shows schematically, a sectional view of an example embodiment of a MEMS oscillating element in an undeflected configuration, according to the present invention.

FIGS. 3A and 3B show schematically, sectional views of an example embodiment of a MEMS oscillating element in a deflected configuration, according to the present invention.

FIGS. 4A and 4B show schematically, sectional views of an example embodiment of an actuator component, according to the present invention.

FIG. 5 show schematically, a sectional view of an example embodiment of a MEMS oscillating element, according to the present invention.

FIG. 6 show schematically, a sectional view of an example embodiment of an actuator component, according to the present invention.

### DETAILED DESCRIPTION OF EXAMPLE EMBODIMENTS

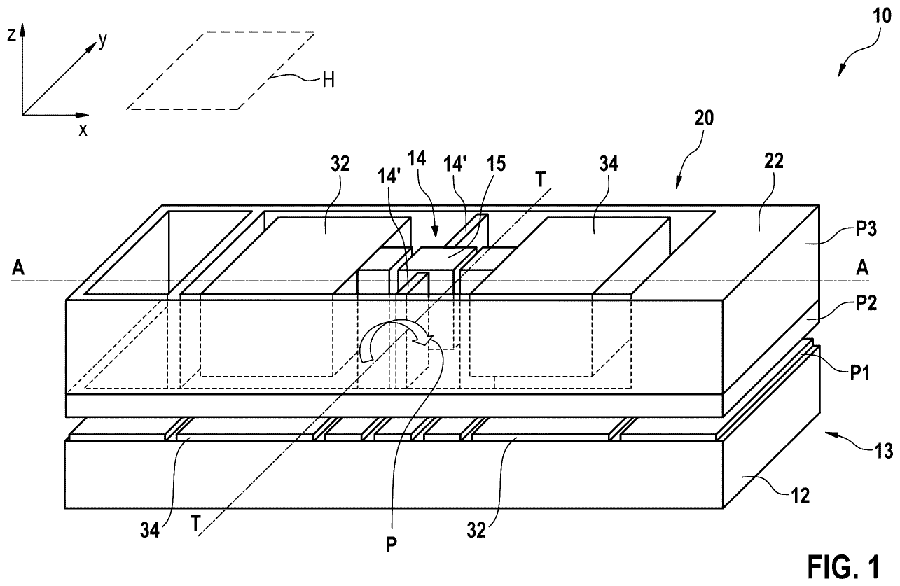

The structure and functioning of a MEMS oscillating element along with a method for operating a MEMS oscillating element are described schematically below with reference to FIGS. 1 to 6. Corresponding reference symbols are used for corresponding features.

FIG. 1 shows a MEMS oscillating element 10, which is designed as a capacitive MEMS inertial sensor. In this embodiment, the MEMS oscillating element 10 serves to measure accelerations and has a detection direction z perpendicular to a virtual main extension plane H, which, in the embodiment shown in the figure, is defined by the x-and y-axes of the illustrated Cartesian coordinate system. The present invention is described below based on a MEMS inertial sensor, but it can also be used for other deflectable MEMS components such as MEMS switches, gyroscopes, resonators or micromirrors.

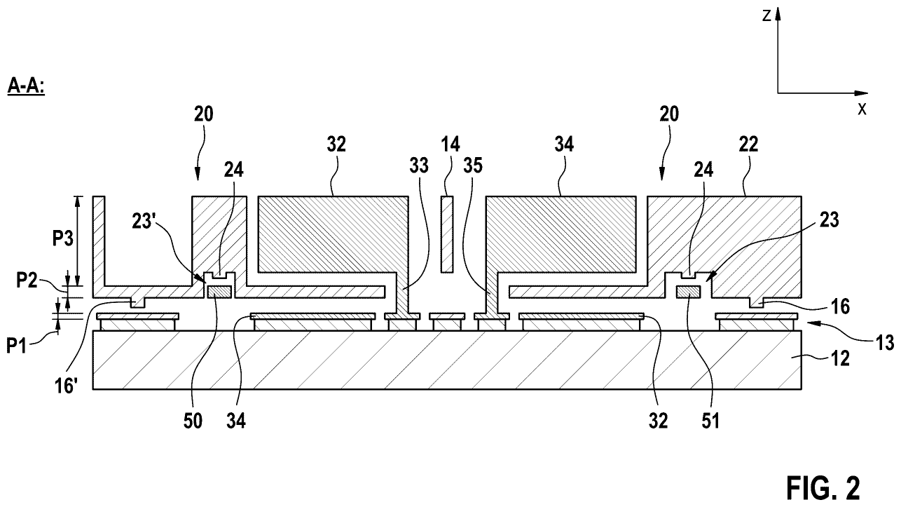

The MEMS oscillating element 10 is designed as a “rocker”; FIGS. 1 and 2 show the MEMS oscillating element 10 in an undeflected configuration. The sensor principle of such a rocker is based on a spring-mass system, in which a component 20, which is movable about a torsion axis TT and acts as a movable electrode, is deflected by acting accelerations relative to a non-movable first component 13. On the first component 13, which comprises a substrate 12, two counter electrodes 32, 34 are arranged, which in the embodiment shown are self-supporting and form two plate capacitors with the movable electrode. The movable component 20, which is also referred to as a seismic mass within the framework of the application and in connection with the embodiment of the MEMS oscillating element 10 as a MEMS inertial sensor, is fastened to the first component 13 in a suspension region 14 in such a way that the movable component 20 is rotatable about the torsion axis TT relative to the first component 13.

In the suspension region 14, at least one, usually two for reasons of symmetry, torsion spring 14′is also arranged, which acts on the movable component 20 with a restoring force relative to the first component 13 when it moves about the torsion axis T-T, as indicated in the figure by an arrow P about the torsion axis T-T. In FIG. 1, the torsion springs 14′are designed as web regions extending along two opposite sides of a central fastening region 15.

As can be seen in particular from FIG. 2, which shows a schematic representation of the MEMS oscillating element 10 in a cross-section along the axis A - A in FIG. 1, the first counter electrode 32 is connected to the first component 13 in a first connection region 33, while the second counter electrode 34 is connected to the first component 13 in a second connection region 35. The first connection region 33 and the second connection region 35 are in each case arranged perpendicular to the torsion axis TT and parallel to the main extension plane H in the region of the suspension region 14 and/or immediately adjacent to the suspension region 14.

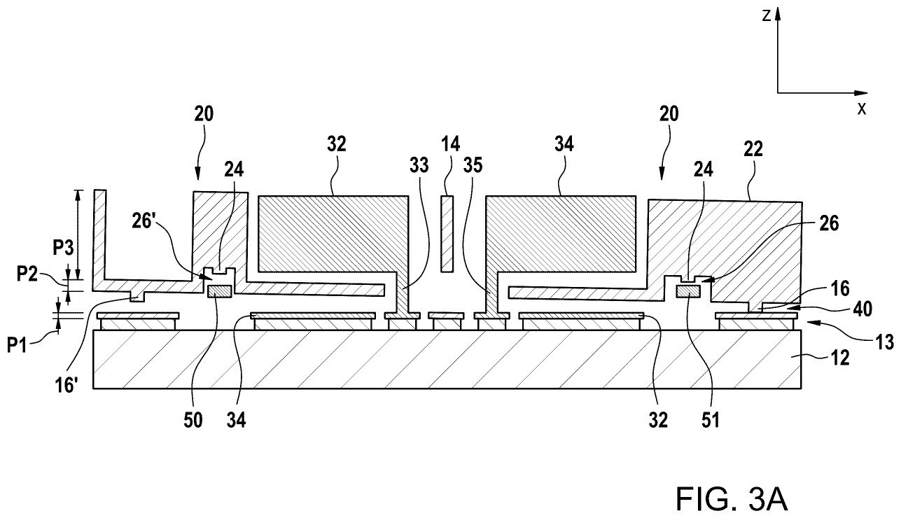

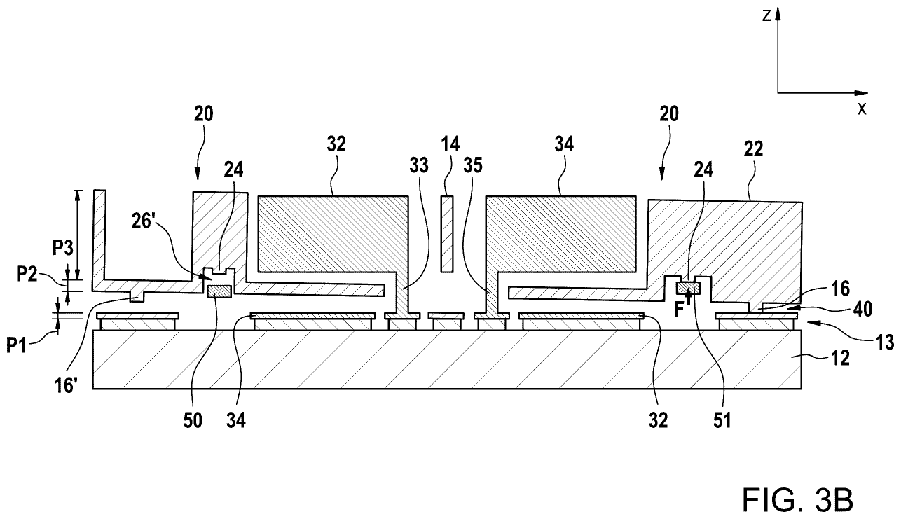

The movable component 20 comprises a mass element 22 on one side of the torsion axis TT, which causes an asymmetric mass distribution of the movable component 20 with respect to the torsion axis TT. The inertial forces associated with the mass element 22 result in a torque acting on the movable component 20 when the MEMS oscillating element 10 is accelerated perpendicular to the main extension plane H. Depending on the direction of acceleration, the electrode pairs approach one another on one side of the torsion axis TT, while they move away from one another on the opposite side. This deflected state of the MEMS oscillating element 10 is shown in FIG. 3A, which will be discussed in more detail later. The amount of deflection of the movable component 20 is evaluated capacitively by means of the counter electrodes 32, 34, and thus the change in capacitance is the measure of the acting acceleration.

The first counter electrode 32 and the second counter electrode 34 are arranged “above” the movable component 20, i.e. the movable component 20 is arranged in the region of the counter electrodes 32, 34 and in the z-direction perpendicular to the main extension plane H between the first component 13 and the first counter electrode 32 or the second counter electrode 34, respectively. The counter electrodes 32 and 34 are designed as self-supporting electrodes, which are fastened to the first component 13 by means of a connection region 33 and 35, respectively. In order for a deformation of the substrate 12 to have as little influence as possible on the geometry between the movable component 20 and the counter electrodes 32 and 34, and in particular on the distance between the movable component 20 and the counter electrodes 32 and 34 in the z-direction perpendicular to the main extension plane H, the connection regions 33 and 35, respectively, are arranged in the region of the suspension region 14. The connection regions 33 and 35 are arranged in the regions of the counter electrodes 32 and 34 facing the torsion axis TT, such that the distance between the torsion axis TT and the connection regions 33 and 35 perpendicular to the torsion axis TT and parallel to the main extension plane H is minimal. The second counter electrode 34 is essentially identical in construction to the first counter electrode 32, wherein the second counter electrode 34 is mirror-symmetrical to the first counter electrode 34 with respect to the torsion axis TT.

As shown in FIGS. 1 and 2, the MEMS oscillating element 10 comprises a layer structure with a first layer P1, a second layer P2, and a third layer P3, wherein the layers P1, P2, and P3 preferably comprise silicon and are also referred to as P1 plane, P2 plane, and P3 plane within the framework of the application. The counter electrodes 32 and 34 are in each case arranged in some regions both as top electrodes in the P3 plane and, in relation to the torsion axis TT on opposite sides, as bottom electrodes in the P1 plane, wherein the regions arranged in the different layers are electrically interconnected. To determine capacitance changes, the difference signal of the two counter electrodes 32, 34 is electrically evaluated. The arrangement shown in the figures exhibits a particularly high capacitance density, i.e. capacitance per area, due to the use of top and bottom electrodes, and also a high tolerance to bending stresses on the substrate 12, since the top electrodes are suspended centrally and the bottom electrodes can be made very compact due to the additional capacitance formed by the top electrodes. Both aspects lead to lower offset and sensitivity drifts of the sensor component under bending stress, for example due to circuit board bending or thermomechanical stresses, and thus to a more robust and overload-resistant sensor design.

FIG. 3A shows the MEMS sensor 10 shown in FIG. 2 in a deflected configuration, in which the movable component 20 is rotated about the torsion axis TT relative to the non-deflected configuration. While, as described above, the change in capacitance due to the deflection of the movable component 20 is the measure of the acceleration acting on the MEMS sensor 10, FIG. 3A shows a state in which the movable component 20 is deflected by an overload acceleration. As can be seen in the figure, the movable component 20 is deflected so far in the configuration shown that a stop component 16 arranged on the movable component 20 contacts the first component 13. The configuration of the movable component 20 shown in FIG. 3A is also referred to as the stop position in the application. The movable component 20 thus contacts the first component 13 in the stop position, namely at a stop point 40 that lies in the region of the stop component 16. The limitation of the deflection of the movable component 20 by the stop component 16 is intended to prevent damage to the MEMS oscillating element 10 due to excessive deflection of the movable component 20. In the embodiment shown, the MEMS oscillating element 10 in each case comprises at least one stop component 16 on each side of the torsion axis TT. This ensures that when the movable component 20 is deflected due to overload acceleration and regardless of the direction in which the movable component 20 is deflected, a stop component 16 always strikes the first component 13.

As already explained above, the MEMS oscillating element 10 can experience so-called stiction due to frequently repeated shock loads, in which the movable component 20 remains stuck in the stop position as soon as the adhesion forces in the stop point 40 are greater than the restoring forces of the spring-mass system. The stop components 16 serve to reduce the risk of stiction, but even the arrangement of the stop components 16 cannot completely eliminate the risk of a stiction state occurring.

In order to eliminate such a stiction state, the MEMS oscillating element 10 comprises at least one, two in the embodiment shown, actuator components 50, 51. In the embodiment in FIGS. 2, 3A, 3B, and 5, the MEMS oscillating element comprises a first actuator component 50 and a second actuator component 51, wherein the first actuator component 50 and the second actuator component 51 are arranged in a plane parallel to the main extension plane H and in relation to the torsion axis TT on opposite sides of the torsion axis TT. As indicated in FIG. 3B by the arrow F, the actuator components 50, 51, which are identical in the embodiment in FIGS. 3A and 3B, are configured to transmit a force F between the first component 13 and the movable component 20 if the movable component 20 is in the stop position, and thus to return the MEMS oscillating element 10 to a non-stiction state by targeted actuation. When actuated, the actuator component 50, 51 carries out a movement in some regions that bridges a gap 26, 26′ existing in the non-actuated state of the actuator component 50, 51 between the actuator component 50, 51 and the movable component 20 or, depending on the embodiment, between the actuator component 50, 51 and the first component 13. It can be said that the actuator component 50, 51 in the deformed configuration is arranged closer to the movable component and further spaced away from the first component than in the undeformed configuration. The structure and function of the actuator components 50, 51 are described in more detail below.

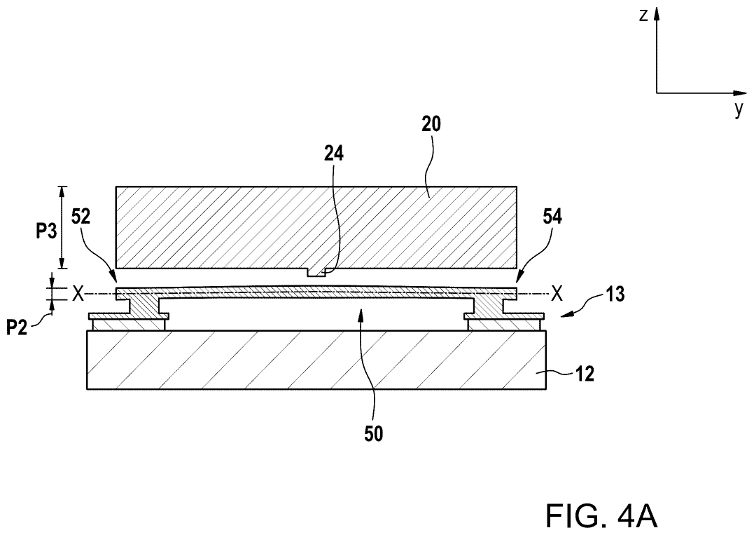

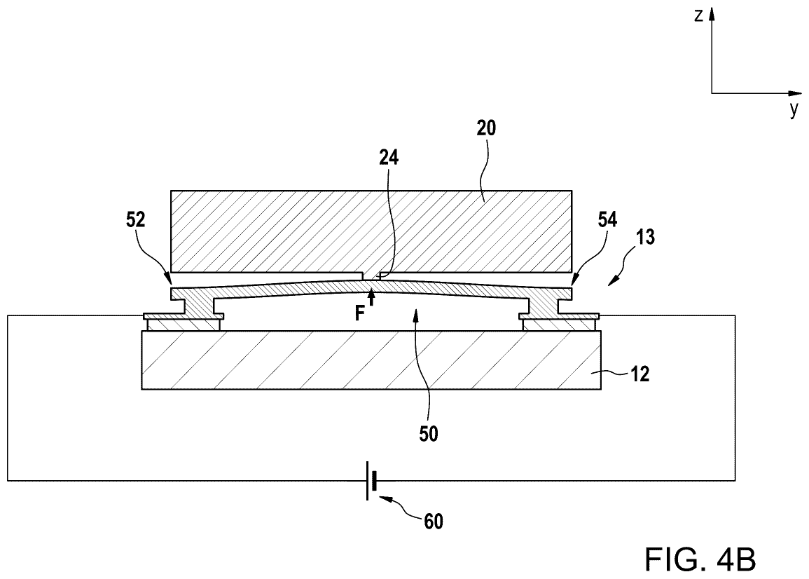

Each of the actuator components 50, 51 is designed, as shown in FIG. 4A, as a free-standing bending beam clamped at a first end 52 and a second end 54 with a beam longitudinal axis X-X running perpendicular to the first direction z. It should be noted that FIGS. 4A and 4B shows a sectional view of the actuator element and the movable component 20 in the y-z plane, which is oriented perpendicular to the x-z plane in FIGS. 2, 3A, and 3B. In the embodiment shown, the movable component 20 comprises a stop 24 that serves as a stop point for the actuator component 50 and is arranged above the actuator component 50 in the P3 plane. In the embodiment shown in FIGS. 4A and 4B, the actuator component 50, 51 is formed in the P2 plane and mounted on the substrate 12 and selectively assumes an undeformed configuration shown in FIG. 4A along with a deformed configuration shown in FIG. 4B, in which it is deflected at least partially perpendicular to its beam longitudinal axis X-X and exerts a force F in the z-direction on the movable component.

The actuation of the respective actuator component 50, 51, i.e. the transfer from the undeformed to the deformed configuration, is achieved by means of a voltage supply device 60, which is configured in such a way that a voltage can be selectively applied to the respective actuator component 50, 51, for example between the first end 52 and the second end 54. For this purpose, the actuator components 50, 51 are connected to the voltage supply device via contact pads and electrical conductors (not shown). The respective actuator component 50, 51 is consequently heated by electrical resistance heating and is heated from a first temperature to a buckling temperature. When the buckling temperature is reached, the respective actuator component 50, 51 is transferred from the undeformed to the deformed configuration, in which it exerts the actuator force F on the movable component 20. As soon as the sum of actuator force F and spring return force of the torsion spring is greater than the adhesion force on the stop component 16, the MEMS oscillating element 10 is released from the stiction state and is functional again.

In embodiments of the MEMS oscillating element 10, the actuator component 50, 51 changes in an abrupt, jumplike manner from the undeformed configuration to the deformed configuration. This effect, also known as buckling, can be achieved by appropriate selection of the geometry, bearing and material properties of the actuator component 50, 51, which will be discussed in more detail later. During the abrupt buckling into the deformed configuration, the respective actuator component 50, 51 exerts a mechanical impulse on the first component 13 and/or the movable component 20 of the movable component 20 is in the stop position. By appropriate selection of the material and geometric properties of the actuator component 50, 51, the magnitude of the mechanical impulse is adjusted in such a way that the stiction state between the first component 13 and the movable component 20 is released.

Preferably, the actuator component 50, 51 exhibits a slight initial deformation perpendicular to the beam longitudinal axis X-X and in the direction of the desired buckling, i.e. in the +z direction in the embodiment shown in FIGS. 4A and 4B. In embodiments of the MEMS oscillating element 10, this is achieved by a doping profile of foreign atoms, which are introduced into the P2 layer to increase conductivity, being selected such that a slight voltage gradient is formed in the z-direction. In this way, the desired position of the deformed configuration relative to the undeformed configuration is predetermined, in such a way that the actuator component 50, 51 buckles in the direction of the movable component 20.

The MEMS oscillating element 10 can comprise a control device, which is not shown in the figures for the sake of clarity. The control device, which in embodiments comprises an ASIC (application-specific integrated circuit), is connected to the voltage supply device and is configured to detect a stiction state between the first component 13 and the movable component 20 and to apply a voltage to the at least one actuator component 50, 51 via the voltage supply device 60.

From an electrical engineering point of view, the actuator components 50, 51 together with the current conductors represent resistive elements for the ASIC. The stiction state can be detected, for example, in that an output signal of the MEMS oscillating element 10 permanently lies outside the measurement range or above a certain threshold value. It is also determined on which side of the torsion spring the stiction state between the movable component 20 and the first component 13 exists. The respective actuator component 50, 51, which is arranged on the side of the torsion spring on which the stiction state is detected, is then subjected to a voltage on the ASIC side. As soon as an electric current flows through the actuator component 50, 51, the corresponding actuator component 50, 51 heats up due to resistance heating. The actuator component 50, 51 and its supply lines are advantageously dimensioned such that the voltage drop occurs mainly in the actuator component 50, 51. This is achieved in embodiments by the supply lines being short and wide, and possibly particularly highly doped, i.e. low-resistance, and the actuator component 50, 51 being designed with a small cross-sectional area, i.e. high resistance. Since the actuator component 50, 51 consequently heats up considerably, but the substrate 12 of the MEMS sensor 10 hardly heats up, high mechanical stresses develop in the actuator component 50, 51 even at low electrical voltages due to the different thermal expansion between the actuator component 50, 51 and the substrate 12, including the mechanical anchorings of the actuator component 50, 51 on both sides. At a defined, sufficiently high mechanical stress state, the actuator component 50, 51 buckles, thus suddenly changing from the undeformed to the deformed configuration. In embodiments, the dimension of the actuator component 50, 51 in the x-direction is significantly larger than that in the z-direction, i.e. it is significantly wider than thick, as a result of which it is guaranteed that buckling always takes place in the z-direction and not laterally in the x-direction.

As soon as the control device or the ASIC registers the release of the movable component 20, the voltage applied to the actuator component 50, 51 is reset to zero. The actuator component 50, 51 then cools down and, after complete cooling, returns to the undeformed configuration shown in FIG. 4A.

In embodiments of the MEMS oscillating element 10, a pulsed operation of the actuator component 50, 51 is used in order to initiate a plurality of buckling events in short succession and thus to achieve a release of the second component 20 by frequently repeated tapping of the latter. Here, the actuator component 50, 51 is converted from the undeformed configuration to the deformed configuration in a series of temporally spaced pulses.

In embodiments of the MEMS oscillating element 10, the control device is configured to increase the voltage applied to the actuator component 50, 51 while the actuator component 50, 51 is in the deformed configuration. As a result, a greater force can be exerted on the movable component 20 in the +z direction. In this case, it is not the sudden impulse input, but a continuously increased force by which a release of the movable component 20 is achieved.

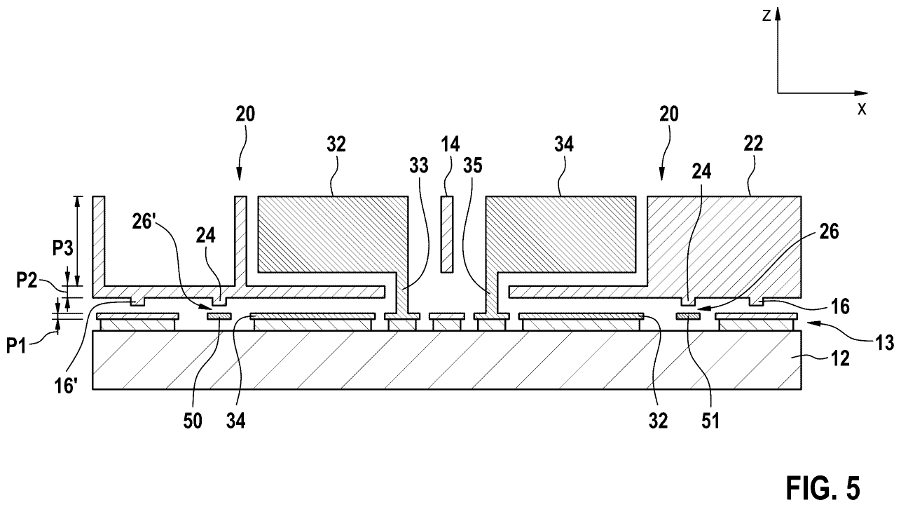

FIG. 5 shows an embodiment of the MEMS oscillating element 10 in which the actuator component 50, 51 is not arranged in the P2 layer but in the P1 layer, but as in the embodiment described above, between the substrate 12 and the movable component 20. The embodiment shown in FIG. 5 is technically particularly advantageous if the thickness of the P1 layer is between approximately 1 and 3 μm. It has been found that with thinner layers, the mechanical stability of the actuator component 50, 51 may be too low when impacted; in addition, very thin exposed layers typically exhibit relatively high curvatures even when clamped on one side, which makes the design of a longer bending beam clamped on both sides technically challenging. However, if the P1 layer is thicker than approximately 3 μm, it has been found that it is difficult to form the actuator component 50, 51 in such a way that it buckles in the desired manner upon heating.

A particularly advantageous feature of the embodiment shown in FIG. 5 is that the required intervention in the topology of the movable sensor structure is particularly small, as shown, for example, by comparing FIG. 5 with FIG. 2. For example, in the embodiment shown in FIG. 5, it is not necessary to form the recesses 23 marked in FIG. 2 in the movable component 20, in order to create construction space for the actuator components 50, 51.

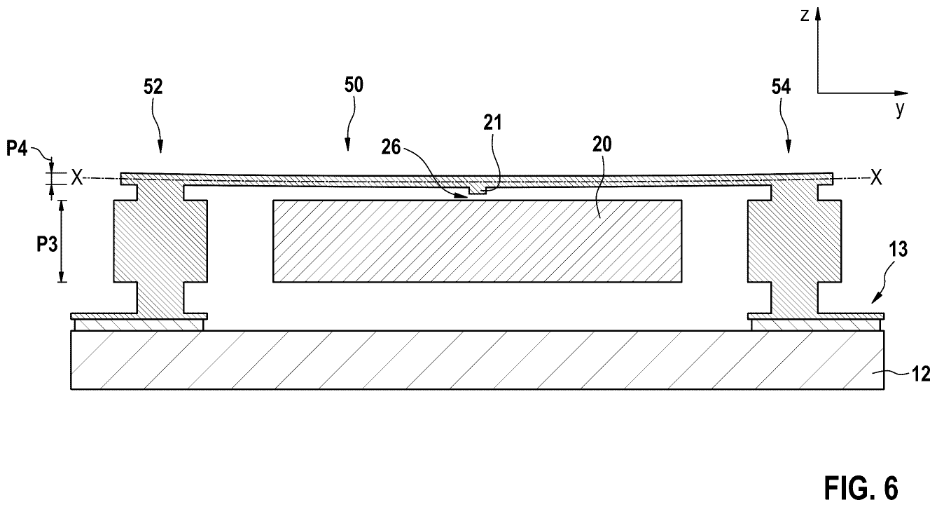

FIG. 6 shows selected components of another embodiment of the MEMS oscillating element 10 in a sectional view. In this embodiment, the actuator component 50 is not arranged below, but above the movable component 20. This can be achieved, for example, by surface micromechanical methods, in that a P4 layer, preferably with a layer thickness in the range of 1-3 μm, is arranged above the P3 layer and suitably structured. In order for the buckling of the actuator element 50 to take place in a defined direction in the direction of the movable component 20, i.e. in this case “down” in the figure in the negative z-direction, the pre-deflection of the bending beam realized in the P4 layer is applied opposite to the positive z-direction shown in FIG. 6. A further special feature of the embodiment shown in FIG. 6 is that the movable component 20 does not comprise a stop 24. Instead, a stop element 21 is formed on the movable component 20, via which the force is transmitted to the movable component 20 in the deflected configuration of the actuator component 50.

The present invention is not limited to the described and illustrated embodiments. Rather, it also comprises all further developments of a person skilled in the art within the scope of the present invention. In addition to the described and depicted embodiments, further embodiments, which can include additional variations and combinations of features, are possible.

What is claimed is:

1. A micro-electromechanical oscillating element, comprising:
a first component;
a movable component mounted so as to be movable relative to the first component at least in a first direction, wherein the movable component assumes a stop position relative to the first component in the event of a sufficiently large deflection, wherein the movable component contacts the first component in the stop position at least at a first stop point;
at least one actuator component, which is configured as a bending beam, is clamped on both sides with a beam longitudinal axis running perpendicular to the first direction, wherein the at least one actuator component is configured, according to an activation, to selectively assume an undeformed configuration and a deformed configuration, in which the at least one actuator component is deflected at least partially perpendicular to the beam longitudinal axis, wherein the at least one actuator component is configured, in the deformed configuration, to transmit a force between the first component and the movable component if the movable component is in the stop position.

2. The MEMS oscillating element according to claim 1, wherein the at least one actuator component is configured to change from the undeformed configuration to the deformed configuration when subjected to a voltage, wherein the at least one actuator component is heated from a first temperature to a buckling temperature and is transferred from the undeformed to the deformed configuration.

3. The MEMS oscillating element according to claim 2, wherein the at least one actuator component is configured in such a way that when the buckling temperature is reached, the at least one actuator component buckles in a jumplike manner from the undeformed configuration to the deformed configuration.

4. The MEMS oscillating element according to claim 3, wherein the at least one actuator component is configured in such a way that, upon buckling into the deformed configuration, the at least one actuator component exerts a mechanical impulse on the first component and/or the movable component if the movable component is in the stop position.

5. The MEMS oscillating element according to claim 4, wherein the at least one actuator component is configured in such a way that the mechanical impulse releases a stiction state between the first component and the movable component.

6. The MEMS oscillating element according to claim 1, wherein the at least one actuator component exhibits an initial deformation perpendicular to the beam longitudinal axis in the undeformed configuration, such that a position of the deformed configuration relative to the undeformed configuration is predetermined.

7. The MEMS oscillating element according to claim 6, wherein the at least one actuator component is arranged closer to the movable component and further spaced away from the first component n the deformed configuration than in the undeformed configuration.

8. The MEMS oscillating element according to claim 5, further comprising:
a control device that is connected to a voltage supply device and is configured to detect a stiction state between the first component and the movable component and to apply a voltage to the at least one actuator component via the voltage supply device.

9. The MEMS oscillating element according to claim 8, wherein the control device is configured to apply a voltage to the at least one actuator component in such a way that the at least one actuator component buckles from the undeformed configuration into the deformed configuration in a series of temporally spaced pulses.

10. The MEMS oscillating element according to claim 8, wherein the control device is configured to increase the voltage applied to the at least one actuator component while the at least one actuator component is in the deformed configuration.

11. The MEMS oscillating element according to claim 1, wherein the MEMS oscillating element is a MEMS sensor element and the movable component is a seismic mass.

12. The MEMS oscillating element according to claim 11, wherein the MEMS oscillating element includes a substrate with a main extension plane and at least one at least partially self-supporting electrode, and wherein:
the movable component is movably fastened to the substrate in a suspension region about a torsion axis parallel to the main extension plane,
the movable component exhibits an asymmetric mass distribution with respect to the torsion axis,
the at least one electrode is connected to the substrate in a connection region, and
the connection region is arranged perpendicular to the torsion axis and parallel to the main extension plane in a region of the suspension region and/or immediately adjacent to the suspension region.

13. The MEMS oscillating element according to claim 12, wherein the at least one electrode is arranged in a direction perpendicular to the main extension plane between the movable component and the substrate or the movable component is arranged in the direction perpendicular to the main extension plane between the at least one electrode and the substrate.

14. The MEMS oscillating element according to claim 12, wherein in each case an electrode is arranged both above and below the movable component in a direction perpendicular to the main extension plane.

15. The MEMS oscillating element according to claim 12, wherein the beam longitudinal axis of the at least one actuator component is arranged parallel to the main extension plane of the substrate.

16. The MEMS oscillating element according to claim 15, wherein the at least one actuator component is arranged above or below the movable component.

17. The MEMS oscillating element according to claim 12, further comprising:
a first actuator component and a second actuator component, wherein the first actuator component and the second actuator component are arranged in a plane parallel to the main extension plane and in relation to the torsion axis on opposite sides of the torsion axis.

18. A method for operating a micro-electromechanical oscillating element, the MEMS oscillating element including a first component, a movable component mounted so as to be movable relative to the first component at least in a first direction and that contacts the first component in a stop position upon a sufficiently large deflection, and at least one actuator component that is configured as a bending beam clamped on both sides with a beam longitudinal axis running perpendicular to the first direction and that selectively assumes an undeformed configuration and a deformed configuration, in which the at least one actuator component is deflected at least partially perpendicular to the beam longitudinal axis, the method comprising the following steps:
S1) recognizing a stiction state in which the movable component is held to the first component by a force; and
S2) heating the at least one actuator component in such a way that the at least one actuator component buckles perpendicular to the longitudinal axis of the beam from the undeformed to the deformed configuration and releases the movable component from the first component by a mechanical impulse.

19. The method according to claim 18, wherein step S2 includes applying a voltage to the at least one actuator component to heat the at least one actuator component by electrical resistance heating.

20. The method according to claim 18, further comprising the following steps:
S3) recognizing that the stiction state no longer exists;
S4) transferring the at least one actuator component from the deformed to the undeformed configuration.

21. The method according to claim 20, wherein step S4 includes removing a voltage from the at least one actuator component.
